(19) United States
(12) Patent Application Publication
(10) Pub. No.: US 2017/0358739 A1
(43) Pub. Date: Dec. 14, 2017

(54) ELECTRONIC DEVICE AND METHOD FOR FABRICATING THE SAME

(71) Applicant: SK hynix Inc., Icheon-Si (KR)

(72) Inventors: Jeong-Myeong Kim, Hwaseong-si (KR); Bo-Kyoung Jung, Cheongju-si (KR); Ji-Hun Park, Icheon-si (KR); Min-Suk Lee, Seongnam-si (KR)

(21) Appl. No.: 15/482,525

(22) Filed: Apr. 7, 2017

(30) Foreign Application Priority Data
Jun. 13, 2016 (KR) 10-2016-0072935

(51) Int. Cl. H01L 43/12; H01L 43/02; H01L 27/22

(52) U.S. Cl. CPC H01L 43/12; H01L 27/224; H01L 43/02

(57) ABSTRACT

A method for fabricating an electronic device including a semiconductor memory includes: forming a variable resistance element including material layers over a substrate; forming a hard mask layer including a metal over the material layers; selectively etching the hard mask layer to form an etched hard mask layer; etching the material layers by using the etched hard mask layer as an etch barrier, the etching of the material layers providing an etch byproduct formed on sidewalls of the etched material layers and the etch byproduct including a material that is more readily oxidized than the metal of the hard mask layer; and performing a treatment using a gas or plasma to suppresses oxidation of the hard mask layer and facilitate oxidation of the etch byproducts.

### CROSS-REFERENCE TO RELATED APPLICATIONS

This patent document claims priority of Korean Patent Application No. 10-2016-0072935, entitled “ELECTRONIC DEVICE AND METHOD FOR FABRICATING THE SAME” and filed on Jun. 13, 2016, which is incorporated herein by reference in its entirety.

### TECHNICAL FIELD

This patent document relates to memory circuits or devices and their applications in electronic devices or systems.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes memory circuits or devices and their applications in electronic devices or systems and various implementations of an electronic device which is capable of acquiring low and uniform resistance characteristics of a variable resistance element and preventing undesired current leakage.

In an implementation, a method for fabricating an electronic device including a semiconductor memory includes: forming a variable resistance element including material layers over a substrate; forming a hard mask layer including a metal over the material layers; selectively etching the hard mask layer to form an etched hard mask layer; etching the material layers by using the etched hard mask layer as an etch barrier, the etching of the material layers providing an etch byproduct formed on sidewalls of the etched material layers and the etch byproduct including a material that is more readily oxidized than the metal of the hard mask layer; and performing a treatment using a gas or plasma to suppresses oxidation of the hard mask layer and facilitate oxidation of the etch byproducts.

Implementations of the above method may include one or more the following.

The etch byproduct includes a material whose electron affinity is lower than the metal of the hard mask layer. The etch byproduct includes a material having a standard electrode potential ranging from approximately −2V to approximately −0.5V, and the hard mask layer includes a metal having a standard electrode potential ranging from approximately −0.5V to approximately −0.0V. The etch byproduct includes Si, Ge, Nd, Sc, Th, Be, Al, Ti, Hf, Pa, Zr, Mn, V, Nb, Cr, Zn, or Ta, or a combination thereof, and the hard mask layer includes Mo, Sn, Pb, W, or Re, or a combination thereof. The gas or plasma contains oxygen and at least one of hydrogen, nitrogen, or carbon. The performing of the treatment includes performing an H₂O Inductive Coupled Plasma (ICP) treatment. The forming of the variable resistance element includes: forming a Magnetic Tunnel Junction (MTJ) structure that includes a free layer whose magnetization direction is changeable, a pinned layer whose magnetization direction is fixed, and a tunnel barrier layer which is interposed between the free layer and the pinned layer. The method further includes: forming a lower layer pattern over the substrate to be coupled to the variable resistance element, and include a same material as the etch byproduct. An upper surface of the lower layer pattern is greater than a lower surface of the variable resistance element.

In another implementation, an electronic device includes: a semiconductor memory, wherein the semiconductor memory may include: a substrate; a variable resistance element that is disposed over the substrate; a hard mask pattern that is disposed over the variable resistance element and includes a metal; and a spacer that is disposed on a sidewall of the variable resistance element, wherein the spacer includes an oxide of a first material that is more readily oxidized than the metal of the hard mask pattern.

Implementations of the above device may include one or more the following.

The oxide of the first material has an insulating property. The first material has a lower electron affinity than the metal of the hard mask pattern. The first material has a standard electrode potential ranging from approximately −2V to approximately −0.5V, and the metal has a standard electrode potential ranging from approximately −0.5V to approximately −0.0V. The first material includes Si, Ge, Nd, Sc, Th, Be, Al, Ti, Hf, Pa, Zr, Mn, V, Nb, Cr, Zn, or Ta, or a combination thereof, and the metal includes Mo, Sn, Pb, W, or Re, or a combination thereof. The variable resistance element includes: a Magnetic Tunnel Junction (MTJ) structure that includes a free layer whose magnetization direction is changeable, a pinned layer whose magnetization direction is fixed, and a tunnel barrier layer which is interposed between the free layer and the pinned layer. The variable resistance element includes a lower layer pattern that is coupled to the MTJ structure under the MTJ structure, and the lower layer pattern includes the first material. An upper surface of the lower layer pattern is greater than a lower surface of the MTJ structure.

In another implementation, an electronic device includes: a semiconductor memory, wherein the semiconductor memory may include: a substrate; a variable resistance element formed over the substrate and including a lower portion having a first width and a remaining portion having a second width smaller than the first width, the lower portion including a material; and a hard mask pattern that is disposed over the variable resistance element and includes a metal; and wherein the material has electron affinity lower than the metal of the hard mask layer.

Implementations of the above device may include one or more the following.

The electronic device further comprises a spacer formed on a sidewall of the variable resistance element and includes an oxide of the material. The spacer includes insulating property. The material includes Si, Ge, Nd, Sc, Th, Be, Al, Ti, Hf, Pa, Zr, Mn, V, Nb, Cr, Zn, or Ta, or a combination thereof. The metal includes Mo, Sn, Pb, W, or Re, or a combination thereof. The electronic device further comprises a contact plug formed over the variable resistance element and including a conductive material.

The electronic device may further include a microprocessor which includes: a control unit configured to receive a signal including a command from an outside of the microprocessor, and performs extracting, decoding of the command, or controlling input or output of a signal of the microprocessor; an operation unit configured to perform an operation based on a result that the control unit decodes the command; and a memory unit configured to store data for performing the operation, data corresponding to a result of performing the operation, or an address of data for which the operation is performed, wherein the semiconductor memory is part of the memory unit in the microprocessor.

The electronic device may further include a processor which includes: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory is part of the cache memory unit in the processor.

The electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between at least one of the processor, the auxiliary memory device and the main memory device and the outside, wherein the semiconductor memory is part of the auxiliary memory device or the main memory device in the processing system.

The electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory is part of the storage device or the temporary storage device in the data storage system.

The electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory is part of the memory or the buffer memory in the memory system.

These and other aspects, implementations and associated advantages are described in greater detail in the drawings, the description and the claims.

### BRIEF DESCRIPTION OF THE DRAWINGS

FIGS. 1A to 1C are cross-sectional views describing a method for fabricating a semiconductor memory in accordance with a comparative example.

FIGS. 2A to 2D are cross-sectional views describing a semiconductor memory and a method for fabricating the semiconductor memory in accordance with an implementation of the present disclosure.

FIG. 3 is a graph showing contact resistances and resistance distribution of the semiconductor memory fabricated in accordance with the comparative example and the semiconductor memory fabricated in accordance with the implementation of the present disclosure.

FIG. 4 is an example of configuration diagram of a microprocessor implementing memory circuitry based on the disclosed technology.

FIG. 5 is an example of configuration diagram of a processor implementing memory circuitry based on the disclosed technology.

FIG. 6 is an example of configuration diagram of a system implementing memory circuitry based on the disclosed technology.

FIG. 7 is an example of configuration diagram of a data storage system implementing memory circuitry based on the disclosed technology.

FIG. 8 is an example of configuration diagram of a memory system implementing memory circuitry based on the disclosed technology.

### DETAILED DESCRIPTION

Various examples and implementations of the disclosed technology are described below in detail with reference to the accompanying drawings.

The drawings may not be necessarily to scale and in some instances, proportions of at least some of structures in the drawings may have been exaggerated in order to clearly illustrate certain features of the described examples or implementations. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure may not show or reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

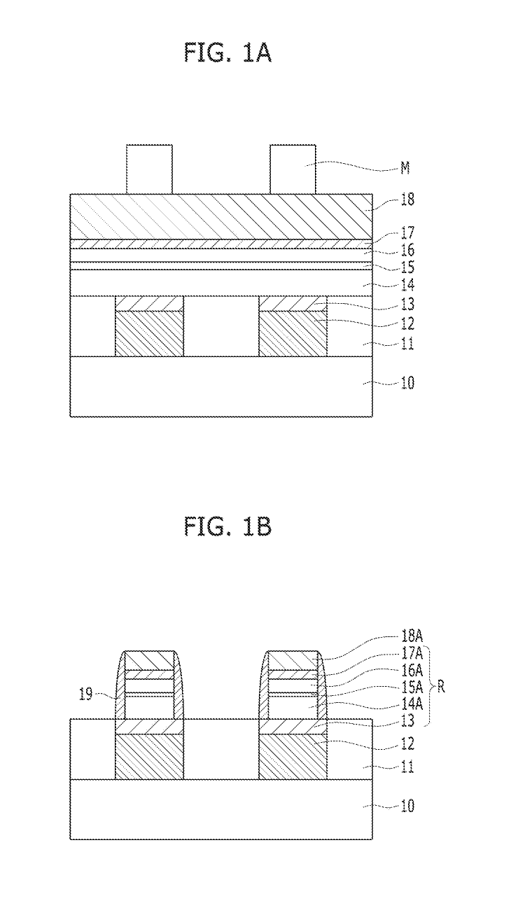

FIGS. 1A to 1C are cross-sectional views describing a method for fabricating a semiconductor memory in accordance with a comparative example. This memory may include memory cells with a Magnetic Tunnel Junction (MTJ) structure in each cell to store data. Two adjacent memory cells are illustrated as examples. Each MTJ structure includes a free layer 14 having a changeable magnetization direction, a pinned layer 16 having a fixed magnetization direction and a tunnel barrier layer 15 between the two magnetic layers 14 and 16. The tunnel barrier layer 15 is formed of an electrical insulation material that electrically insulates the layers 140 and 160 by prohibiting conduction of electrons but is structured to allow tunneling of electrons according to the voltage or current applied to the MTJ structure. The MTJ structure is configured so that the tunneling of electrons according to the voltage or current applied to the MTJ structure can cause the magnetization of the free layer 14 to change when the applied voltage or current is at or greater than a threshold switching voltage or current. The MTJ structure in each memory cell exhibits different resistance states based on different relative directions between the magnetization directions of the free and pinned layers 14 and 16 and such different resistance states can be used to store data and can be measured for readout by applying a read voltage or current across the MTJ structure with an amplitude less than the threshold switching voltage or current.

In operating such a memory device, the electrical conductive path for each MTJ structure should be spatially confined within the MTJ structure without electrical leakage outside the MTJ structure such as the peripheral regions surrounding the MTJ structure so that the only electrical path between two magnetic layers 14 and 16 is through the carrier tunneling via the insulating barrier layer 15. The disclosed technology for MTJ structures and for fabrication of the MTJ structures can be used to provide a protection layer surrounding each MTJ structure to reduce the undesired electrical leakage and enclose each MTJ structure from its surroundings.

Referring to FIG. 1A, an inter-layer dielectric layer 11 may be formed over a substrate 10.

Subsequently, contact holes that expose a portion of the a substrate 10 are formed, and then lower contact plugs 12 filling the lower portions of the contact holes and lower layer patterns 13 filling the remaining portions of the contact holes over the lower contact plugs 12 are formed. The lower layer pattern 13 may be used as a part of the variable resistance element, which is to be described later, and distinguished from the lower contact plug 12 that is coupled to the lower end of the variable resistance element to couple the variable resistance element to another device. Forming the lower layer patterns 13 to fill the contact holes may help to reduce the etch targets during an etch process for fabricating the variable resistance element and simplify the etch process.

Subsequently, a free layer 14 having a changeable magnetization direction, a tunnel barrier layer 15 that allows tunneling of electrons according to the voltage or current applied thereto, and a pinned layer 16 having a fixed magnetization direction may be sequentially formed over the inter-layer dielectric layer 11 and the lower layer patterns 13. In some implementations, the free layer 14, the tunnel barrier layer 15 and the pinned layer 16 function as material layers for forming a Magnetic Tunnel Junction (MTJ) structure over the inter-layer dielectric layer 11 and the lower layer patterns 13.

Subsequently, an upper layer 17 and a hard mask layer 18 may be formed over the pinned layer 16, and then a mask pattern M for pattering the variable resistance element may be formed over the hard mask layer 18. The hard mask layer 18 may function as an etch barrier during the etch process for fabricating the variable resistance element and may remain even after subsequent processes. The hard mask layer 18 may include a low-resistance metal material while securing an etch selectivity from the upper layer 17, the pinned layer 16, the tunnel barrier layer 15, and the free layer 14.

Referring to FIG. 1B, after the hard mask layer 18 is etched using the mask pattern M as an etch barrier, the upper layer 17, the pinned layer 16, the tunnel barrier layer 15 and the free layer 14 may be etched using at least the etched hard mask layer 18 as an etch barrier so as to form a stacked structure where a free layer pattern 14A, a tunnel barrier layer pattern 15A, a pinned layer pattern 16A, and an upper layer pattern 17A are piled up. The stacked structure 14A, 15A, 16A and 17A and the lower layer pattern 13 may form a variable resistance element R. A portion of the etched hard mask layer 18 may be lost in the course of the etch process for forming the stacked structure 14A, 15A, 16A and 17A, but after all, the hard mask layer 18 may remain in a predetermined thickness in the semiconductor memory. After the stacked structure 14A, 15A, 16A and 17A is formed, the hard mask layer 18 remaining over the stacked structure 14A, 15A, 16A and 17A may be referred to as a hard mask pattern 18A, hereafter.

The stacked structure 14A, 15A, 16A and 17A may have a width smaller than the upper surface of the lower layer pattern 13. In this case, the lower surface of the stacked structure 14A, 15A, 16A and 17A may overlap with a portion of the upper surface of the lower layer pattern 13. Thus, the entire stacked structure 14A, 15A, 16A and 17A may be disposed on the upper surface of the lower layer pattern 13. It is important to dispose the stacked structure 14A, 15A, 16A and 17A on a planar surface. If the layers that form the stacked structure 14A, 15A, 16A and 17A are not disposed on the lower layer pattern 13 and positioned on the interface between the lower layer pattern 13 and the inter-layer dielectric layer 11, the stacked structure 14A, 15A, 16A and 17A are likely to be bent. Thus, the characteristics of the variable resistance element R may be deteriorated. For example, if a portion of the tunnel barrier layer pattern 15A is bent, the deterioration of the variable resistance element R may occur due to Neel Coupling effect.

During the etch process for forming the stacked structure 14A, 15A, 16A and 17A, etch byproducts 19 may be formed on the sidewalls. Particularly, if the width of the stacked structure 14A, 15A, 16A and 17A is smaller than the width of the lower layer pattern 13 and thus the upper surface of the lower layer pattern 13 is exposed during the etch process, a metal material included in the lower layer pattern 13 may be re-deposited on the sidewalls of the stacked structure 14A, 15A, 16A and 17A so as to inevitably form the etch byproducts 19. In some other MTJ fabrication processes without using the disclosed technology, the presence of the etch byproducts 19 outside the MTJ structure may form an unintended bypass electrical path outside the electrical path via carrier tunneling through the barrier layer 15A to cause undesired current leakage between the free layer pattern 14A and the pinned layer pattern 16A outside the intended electrical path through the barrier layer 15A, which are intended to be electrically insulated from each other. To prevent this undesired current leakage, the subsequent process shown in FIG. 1C may be performed.

Referring to FIG. 1C, an oxidation process may be performed so as to oxidize the etch byproducts 19 that include a metal. As a result, the etch byproducts 19 may be changed into spacers 19A that include an insulating metal oxide. The spacers 19A may not only block off current leakage through the sidewalls of the stacked structure 14A, 15A, 16A and 17A but also serve an a protection layer to protect the sidewalls of the stacked structure 14A, 15A, 16A and 17A of the MTJ stack from the surroundings in the subsequent processing and in the final memory device.

During the oxidation process, the hard mask patterns 18A including metal may be oxidized as well. As a result, the hard mask patterns 18A may be changed into final hard mask patterns 18B including an insulating metal oxide. The final hard mask patterns 18B exhibits an increased resistance as compared to the resistance of the hard mask pattern 18A before the change. Moreover, the thickness of the hard mask patterns 18A and/or the final hard mask patterns 18B may be changed according to the position of the variable resistance element R. This is because etch loading may vary with the position. Therefore, in the above fabrication process may lead to an undesired resistance distribution.

However, if the oxidation process is omitted in the hope of avoiding the above undesired resistance distribution problem, the problem of above-described current leakage may not be solved.

An implementation of the present disclosure provides a semiconductor memory fabrication method and the semiconductor memory device that are capable of solving the problems of both the current leakage and high-resistance.

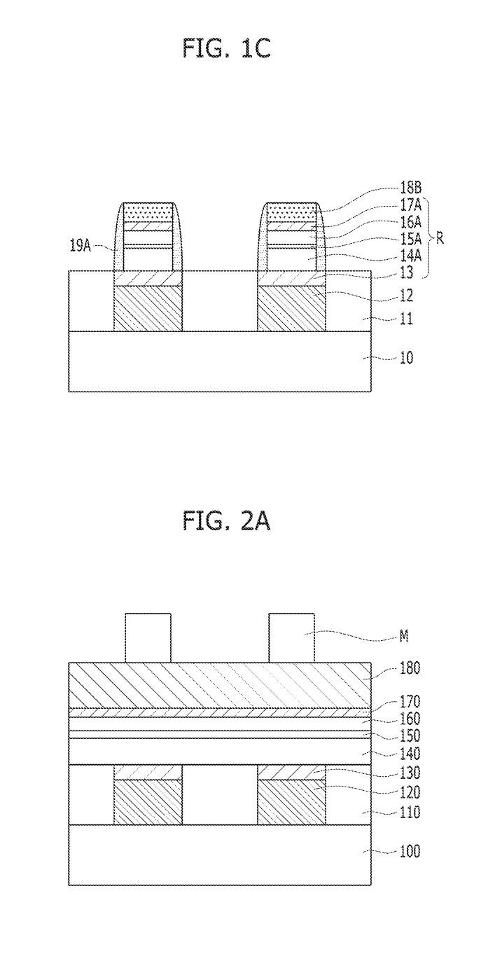

FIGS. 2A to 2D are cross-sectional views describing a semiconductor memory and a method for fabricating the semiconductor memory in accordance with an implementation of the present disclosure.

Referring to FIG. 2A, a substrate 100 where predetermined required structures, such as a switching device (not shown), are formed may be provided. The switching device is coupled to a variable resistance element to control the supply of current or voltage to the variable resistance element. For example, the switching device may include a transistor or a diode. The switching device may have one end to be electrically connected to lower contact plugs 120, which are to be described later, and another end to be electrically connected to a line such as a source line that is not illustrated in the drawing.

Subsequently, a first inter-layer dielectric layer 110 may be formed over the substrate 100. The first inter-layer dielectric layer 110 may be formed of or include various dielectric materials, such as a silicon oxide, or a silicon nitride, or a combination thereof.

Subsequently, contact holes that expose a portion of the substrate 100 may be formed by selectively etching the first inter-layer dielectric layer 110, and then lower contact plugs 120 filling the lower portions of the contact holes may be formed. The lower contact plugs 120 may be formed by depositing a conductive material in a thickness that sufficiently fills the contact holes and then performing an etch-back process on the conductive material in such a manner that the upper surfaces of the lower contact plugs 120 are disposed lower than the upper surface of the first inter-layer dielectric layer 110 by a predetermined height. The lower contact plugs 120 may include a conductive material having excellent filling property and high electrical conductivity, such as tungsten (W), tantalum (Ta), or a titanium nitride (TiN).

Subsequently, lower layer patterns 130 may be formed to fill the remaining portions of the contact holes having the lower contact plugs 120 formed therein. The lower layer patterns 130 may be formed by depositing a conductive material over the contact holes where the lower contact plugs 120 are formed and then performing a planarization process, such as Chemical Mechanical Polishing (CMP), until the first inter-layer dielectric layer 110 is exposed. The lower layer patterns 130 are formed as a part of a variable resistance element, which is to be described later, and the lower layer patterns 130 may be distinguished from the lower contact plugs 120 that are coupled to the lower end of the variable resistance element to couple the variable resistance element to another device. By forming the lower layer patterns 130 to fill the contact holes, the height of the etch targets can be reduced during an etch process for fabricating the variable resistance element, thereby simplifying the etch process. The lower layer patterns 130 may have a single-layer structure or a multi-layer structure including diverse materials for improving the characteristics of the variable resistance element.

The lower layer patterns 130 in accordance with some implementations of the present disclosure may include a material that may be more easily oxidized than that of a hard mask layer 180, which is to be described later. In other words, the lower layer patterns 130 may include a material whose electron affinity is lower than that of the hard mask layer 180. Non-limiting examples of the material for the lower layer patterns 130 may include Si, Ge, Nd, Sc, Th, Be, Al, Ti, Hf, Pa, Zr, Mn, V, Nb, Cr, Zn, or Ta, or a combination thereof, which are materials having standard electrode potential ranging from approximately −2V to approximately −0.5V. When the lower layer patterns 130 have a multi-layer structure, the uppermost layer of the multiple layers may include the material having the above-described property, i.e., being more easily oxidized than the material of the hard mask layer 180. Other layers except for the uppermost layer may be or include layers that perform various functions. For example, one of the layers may be structured to increase adhesiveness to the lower contact plugs 120, or one of the layers may be used to offset the influence of a magnetic field made by a pinned layer 160 on a free layer 140 by having an opposite magnetization direction to the magnetization direction of the pinned layer 160 of an MTJ structure, which is to be described later.

Subsequently, a free layer 140 exhibiting a variable or changeable magnetization direction, a pinned layer 160 having a fixed magnetization direction and a tunnel barrier layer 150 between the layers 140 and 160 that electrically insulates the layers 140 and 160 by prohibiting conduction of electrons while allowing tunneling of electrons according to the voltage or current applied thereto may be sequentially formed as material layers for forming a Magnetic Tunnel Junction (MTJ) structure over the inter-layer dielectric layer 110 and the lower layer patterns 130.

Each of the free layer 140 and the pinned layer 160 may have a single-layer structure or a multi-layer structure that includes a ferromagnetic material. The ferromagnetic material may include alloy containing Fe, Ni or Co as a major component. Non-limiting examples of the alloy may include Fe—Pt alloy, Fe—Pd alloy, Co—Pd alloy, Co—Pt alloy, Fe—Ni—Pt alloy, Co—Fe—Pt alloy, Co—Ni—Pt alloy, Fe—Pd alloy, Co—Pd alloy, Co—Pt alloy, Fe—Ni—Pt alloy, Co—Fe—Pt alloy, or Co—Ni—Pt alloy, Co—Fe—B alloy. The positions of the free layer 140 and the pinned layer 160 relative to the tunnel barrier layer 150 may be changed. For example, although in FIGS. 2A to 2D, the pinned layer 160 is located above the tunnel barrier layer 150 and the free layer 140 is located under the tunnel barrier layer 150, other implementation is also possible. The tunnel barrier layer 150 may change the magnetization direction of the free layer 140 by allowing the tunneling of electrons during a data write operation that changes the resistance state of the variable resistance element. The tunnel barrier layer 150 may include an oxide, such as MgO, CaO, SrO, TiO, VO, or NbO and the like.

Subsequently, an upper layer 170 may be formed over the pinned layer 160. The upper layer 170 forms a part of the variable resistance element, and the upper layer 170 may be distinguished from upper contact plugs (refer to “196” of FIG. 2D) that are coupled to the upper end of the variable resistance element in order to couple the variable resistance element to another device. The upper layer 170 may have a single-layer structure or a multi-layer structure that includes various materials for improving the characteristics of the variable resistance element.

Subsequently, a hard mask layer 180 may be formed over the upper layer 170. The hard mask layer 180 may function as an etch barrier during the etch process for fabricating the variable resistance element and may remain in the final memory device in spite of the subsequent processes to be performed. Therefore, the hard mask layer 180 may include a low-resistance metal material while securing an etch selectivity from the upper layer 170, the pinned layer 160, the tunnel barrier layer 150, and the free layer 140.

In some embodiments, as described above, the hard mask layer 180 may include a metal that may be more reducible than that of the lower layer patterns 130, in other words, a metal having a higher electron affinity than that of the lower layer patterns 130. Non-limiting examples of the metal for the hard mask layer 180 may include Mo, Sn, Pb, W, or Re, or a combination thereof, which have standard electrode potential ranging from approximately −0.5V to approximately −0.0V.

Subsequently, a mask pattern M for patterning the variable resistance element may be formed over the hard mask layer 180.

Referring to FIG. 2B, after the hard mask layer 180 is etched using the mask pattern M as an etch barrier, the upper layer 170, the pinned layer 160, the tunnel barrier layer 150 and the free layer 140 may be etched using at least the etched hard mask layer 18 as an etch barrier so as to form a stacked structure where free layer patterns 140A, tunnel barrier layer patterns 150A, pinned layer patterns 160A, and upper layer patterns 170A are piled up. The stacked structure 140A, 150A, 160A and 170A and the lower layer patterns 130 may form a variable resistance element R. Here, for completely separating the variable resistance element R from another variable resistance element R, the etch process may be performed by an over etching process. Therefore, in this etching process, a portion of the lower layer pattern 130 may be etched last. The etch process may be performed by using great physical etch characteristics, such as the Ion Beam Etching (IBE) method. A portion of the etched hard mask layer 180 may be etched and lost in the course of the etch process that is performed to form stacked structure 140A, 150A, 160A and 170A, but after all, the hard mask layer 180 may remain in a predetermined thickness in the final memory device. After the stacked structure 140A, 150A, 160A and 170A is formed, the hard mask layer 180 remaining in the upper portion of the stacked structure 140A, 150A, 160A and 170A may be referred to as hard mask patterns 180A, hereafter.

Herein, the lower surface of the stacked structure 140A, 150A, 160A and 170A may overlap with the upper surface of the lower layer patterns 130. The lower surface of the stacked structures 140A, 150A, 160A and 170A may have a smaller width than that of the lower layer patterns 130. The entire stacked structure 140A, 150A, 160A and 170A may be disposed over the upper surface of the lower layer patterns 130. By disposing the stacked structure 140A, 150A, 160A and 170A over the upper surface of the planarized lower layer patterns 130, the characteristics of the variable resistance element R can be prevented from being deteriorated.

During the etch process, etch byproducts 190 may be formed on the sidewalls of the stacked structure 140A, 150A, 160A and 170A and the hard mask patterns 180A. Herein, the etch byproducts 190 may mainly include a material that is included in the lower layer patterns 130. This is because the lower layer patterns 130 are etched last and etch byproducts resulting from the layers 140, 150, 160, 170 and 180 etched prior to the lower layer patterns 130 are removed during the etching process. Therefore, the material included in the etch byproducts 190 may be more readily oxidized than that of the hard mask layer 180, and can be, for example, a material whose electron affinity is lower than that of the hard mask layer 180. To prevent current leakage through the etch byproducts 190, the subsequent processes of FIG. 2 may be performed.

Referring to FIG. 2C, the resultant structure obtained from FIG. 2B may be treated with a gas or plasma containing oxygen and hydrogen. For example, the treatment may be or include the Inductive Coupled Plasma (ICP) process. In the ICP process, hydrogen radical, oxygen radical and/or hydroxyl radical may be generated to react with the etch byproducts 190 and the hard mask patterns 180A.

Herein, since the electron affinity of the etch byproducts 190 is lower than the electron affinity of the hard mask patterns 180A, the etch byproducts 190 may be selectively oxidized while the oxidation of the hard mask patterns 180A may be suppressed by the oxygen that is used for the treatment. Even if the hard mask patterns 180A is oxidized to a certain extent, the hard mask patterns 180A may be reduced due to the presence of hydrogen that is also used for the treatment. Therefore, the oxidation of the hard mask patterns 180A can be substantially suppressed. Consequently, while the hard mask patterns 180A are maintained without being oxidized, the etch byproducts 190 may be changed into spacers 190A including an insulating metal oxide. The spacers 190A may include an oxide including Si, Ge, Nd, Sc, Th, Be, Al, Ti, Hf, Pa, Zr, Mn, V, Nb, Cr, Zn, or Ta, or a combination thereof.

The treatment as discussed above may be performed ex-situ, that is, when the substrate structure is exposed to the air. In this case, the etch byproducts 190 and at least a portion of the hard mask patterns 180A may be oxidized due to natural oxidation. However, due to the difference in the electron affinity, the etch byproducts 190 may be selectively oxidized during the treatment, and the oxidized hard mask patterns 180A may be reduced back so that the hard mask patterns 180A may be maintained as conductive.

In this implementation of the present disclosure, the gas or plasma containing oxygen and hydrogen is used during the treatment. However, various kinds of gases or plasmas can be used as long as they are capable of suppressing the oxidation of the hard mask patterns 180A or reducing back the oxidized hard mask patterns 180A while oxidizing the etch byproducts 190. For example, a gas or plasma containing oxygen and nitrogen, such as nitrogen dioxide (NO₂), may be used. In some implementations, a gas or plasma containing oxygen and carbon, such as carbon dioxide (CO₂) may be used.

Referring to FIG. 2D, a capping layer 192 may be formed along the profile of the resultant structure of FIG. 2C, and then a second inter-layer dielectric layer 194 may be formed over the capping layer 192. The capping layer 192 may include an insulating material, such as a silicon nitride, and the second inter-layer dielectric layer 194 may include another insulating material that is different from that of the capping layer 192, such as a silicon oxide. The second inter-layer dielectric layer 194 may have a planarized upper surface. To this end, the second inter-layer dielectric layer 194 may be formed by depositing an insulating material and performing a planarization process.

Subsequently, contact holes that expose at least a portion of an upper surface of the hard mask patterns 180A may be formed by selectively etching the second inter-layer dielectric layer 194 and the capping layer 192. A conductive material may be deposited in a thickness that sufficiently fills the contact holes and then a planarization process may be performed until the second inter-layer dielectric layer 194 is exposed. In this way, upper contact plugs 196 can be electrically connected to the upper end of the variable resistance element R. In this implementation of the present disclosure, the contact holes may be coupled with the upper surface of the hard mask patterns 180A. In some implementations, the depth of the contact holes is increased. For example, the contact holes may be coupled to the upper layer patterns 170A by penetrating through a portion of the hard mask patterns 180A or penetrating through the entire hard mask patterns 180A. The upper contact plugs 196 may include a conductive material having excellent filling property and high electrical conductivity, for example, tungsten (W), tantalum (Ta), or a titanium nitride (TiN).

Subsequently, although not illustrated, lines that are electrically connected to the upper contact plugs 196, e.g., bit lines, may be formed over the second inter-layer dielectric layer 194 and the upper contact plugs 196.

The semiconductor memory shown in FIG. 2D may be fabricated through the process described above.

Referring back to FIG. 2D, the semiconductor memory in accordance with the implementation of the present disclosure may include the lower contact plugs 120 that are disposed over the substrate 100 and coupled to a portion of the substrate 100, the variable resistance element R that is formed over the lower contact plugs 120 to be coupled to the lower contact plugs 120, the conductive hard mask patterns 180A that are disposed over the variable resistance element R and include a metal, the spacers 190A that are disposed on the sidewalls of the variable resistance element R, and the upper contact plugs 196 that are coupled to the variable resistance element R over the variable resistance element R.

Herein, the lower layer patterns 130 that are disposed in the lowermost portion of the variable resistance element R may include a first material that is more readily oxidized than the metal included in the hard mask patterns 180A. The lower layer patterns 130 may have a width greater than the remaining portion of the variable resistance element R. Also, the lower layer patterns 130 may have sidewalls that are aligned with the lower contact plugs 120 over the lower contact plugs 120, as the lower layer patterns 130 fill the first inter-layer dielectric layer 110 together with the lower contact plugs 120. The spacers 190A may include an oxide of the first material, and the oxide of the first material may have an insulating property.

The variable resistance element R may store data by switching between different resistance states according to a voltage or current applied to the upper end and lower end of the variable resistance element R through the lower contact plugs 120 and the upper contact plugs 196. In some implementations, the variable resistance element R may store data as the magnetization direction of the free layer patterns 140A is changed according to the voltage or current applied to the variable resistance element R. When the magnetization directions of the free layer patterns 140A and the pinned layer patterns 160A are parallel to each other, the variable resistance element R may be in a low resistance state and, for example, may store a data of ‘1’. When the magnetization directions of the free layer patterns 140A and the pinned layer patterns 160A are anti-parallel to each other, the variable resistance element R may be in a high resistance state and, for example, may store a data of ‘0’.

The semiconductor memory and the method for fabricating the semiconductor memory described above is capable of preventing current leakage that may occur through the sidewalls of the variable resistance element R by performing the selective oxidation process. Furthermore, the contact resistance between the variable resistance element R and the upper contact plugs 196 may be prevented from being increased by maintaining the metallic property of the hard mask patterns 180A that are disposed between the variable resistance element R and the upper contact plugs 196 through the selective oxidation process and/or the oxidation-reduction process. Since the metallic property of the hard mask patterns 180A is maintained, the distribution of resistance may not be changed although the thickness of the hard mask patterns 180A is different depending on the position. As a result, it is possible to improve data storing characteristics and operation characteristics of the variable resistance element 230.

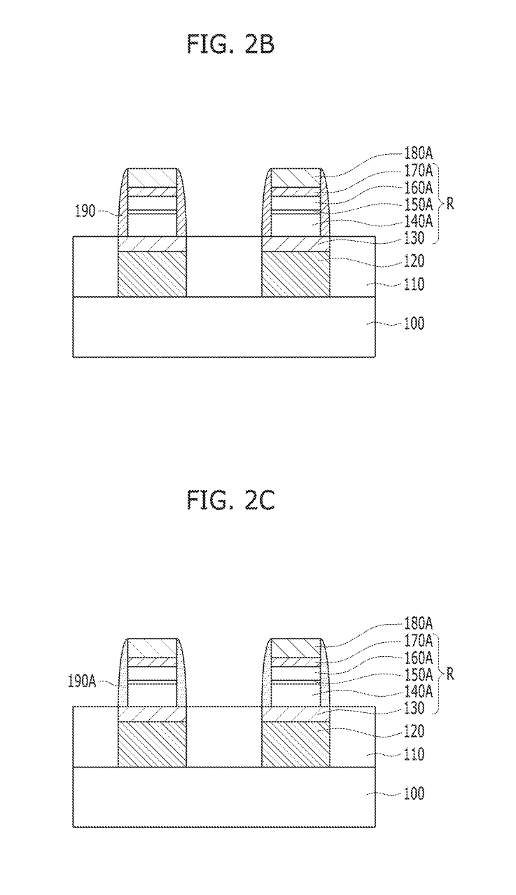

Meanwhile, it is experimentally confirmed that the contact resistance may be decreased and the resistance distribution may be reduced according to the implementations of the present invention. This will be described in detail with reference to FIG. 3.

FIG. 3 is a graph showing contact resistances and resistance distribution of the semiconductor memory fabricated in accordance with the comparative example and the semiconductor memory fabricated in accordance with the implementation of the present disclosure.

Referring to FIG. 3, ‘A’ represents resistance values that were measured when the in-situ oxidation was performed for the oxidation process shown in FIG. 1C. ‘B’ represents resistance values that were measured when the ex-situ natural oxidation process was performed for the oxidation process shown in FIG. 1C. ‘C’ represents resistance values that were measured when an H₂O ICP treatment was performed ex-situ for the selective oxidation process and/or the oxidation-reduction process shown in FIG. 2C. The graph shows that, in the case ‘C’ as compared to the cases ‘A’ and ‘B’, the resistance distribution is the smallest and high-resistance failure is prevented as compared to.

According to the implementations of the present disclosure, it is possible to provide an electronic device which is capable of acquiring low and uniform resistance characteristics of a variable resistance element and preventing current leakage.

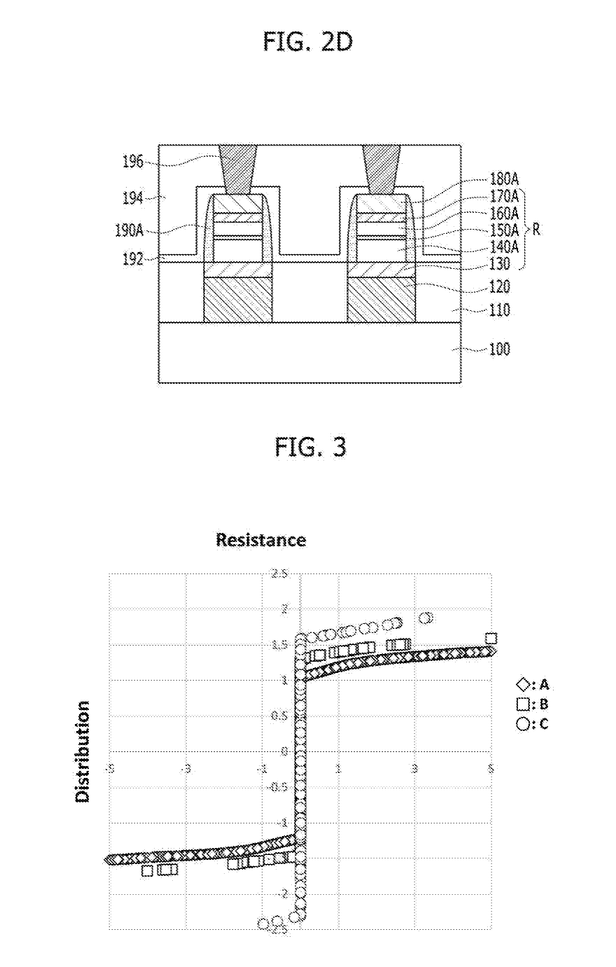

The above and other memory circuits or semiconductor devices based on the disclosed technology can be used in a range of devices or systems. FIGS. 4-8 provide some examples of devices or systems that can implement the memory circuits disclosed herein.

FIG. 4 is an example of configuration diagram of a microprocessor implementing memory circuitry based on the disclosed technology.

Referring to FIG. 4, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations and addresses where data for performing of the operations are stored.

The memory unit 1010 may include one or more of the above-described semiconductor devices in accordance with the implementations. For example, the memory unit 1010 may include a substrate; a variable resistance element that is disposed over the substrate; a hard mask pattern that is disposed over the variable resistance element and includes a metal; and a spacer that is disposed on a sidewall of the variable resistance element, wherein the spacer includes an oxide of a first material that is more readily oxidized than the metal of the hard mask pattern. Through this, data storage characteristics and operating characteristics of the memory unit 1010 may be improved. As a consequence, operating characteristics of the microprocessor 1000 may be improved.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands, and controlling input and output of signals of the microprocessor 1000, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

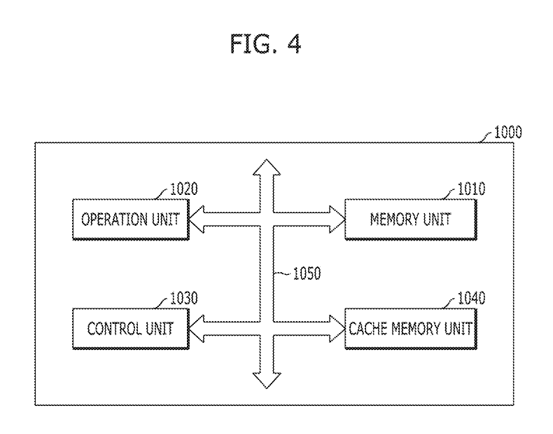

FIG. 5 is an example of configuration diagram of a processor implementing memory circuitry based on the disclosed technology.

Referring to FIG. 5, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and addresses where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor 1100, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage section 1121, a secondary storage section 1122 and a tertiary storage section 1123. In general, the cache memory unit 1120 includes the primary and secondary storage sections 1121 and 1122, and may include the tertiary storage section 1123 in the case where high storage capacity is required. As the occasion demands, the cache memory unit 1120 may include an increased number of storage sections. That is to say, the number of storage sections which are included in the cache memory unit 1120 may be changed according to a design. The speeds at which the primary, secondary and tertiary storage sections 1121, 1122 and 1123 store and discriminate data may be the same or different. In the case where the speeds of the respective storage sections 1121, 1122 and 1123 are different, the speed of the primary storage section 1121 may be largest. At least one storage section of the primary storage section 1121, the secondary storage section 1122 and the tertiary storage section 1123 of the cache memory unit 1120 may include one or more of the above-described semiconductor devices in accordance with the implementations. For example, the cache memory unit 1120 may include a substrate; a variable resistance element that is disposed over the substrate; a hard mask pattern that is disposed over the variable resistance element and includes a metal; and a spacer that is disposed on a sidewall of the variable resistance element, wherein the spacer includes an oxide of a first material that is more readily oxidized than the metal of the hard mask pattern. Through this, data storage characteristics and operating characteristics of the cache memory unit 1120 may be improved. As a consequence, operating characteristics of the processor 1100 may be improved.

Although it was shown in FIG. 5 that all the primary, secondary and tertiary storage sections 1121, 1122 and 1123 are configured inside the cache memory unit 1120, it is to be noted that all the primary, secondary and tertiary storage sections 1121, 1122 and 1123 of the cache memory unit 1120 may be configured outside the core unit 1110 and may compensate for a difference in data processing speed between the core unit 1110 and the external device. Meanwhile, it is to be noted that the primary storage section 1121 of the cache memory unit 1120 may be disposed inside the core unit 1110 and the secondary storage section 1122 and the tertiary storage section 1123 may be configured outside the core unit 1110 to strengthen the function of compensating for a difference in data processing speed. In another implementation, the primary and secondary storage sections 1121, 1122 may be disposed inside the core units 1110 and tertiary storage sections 1123 may be disposed outside core units 1110.

The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be larger than the processing speeds of the secondary and tertiary storage section 1122 and 1123. In another implementation, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

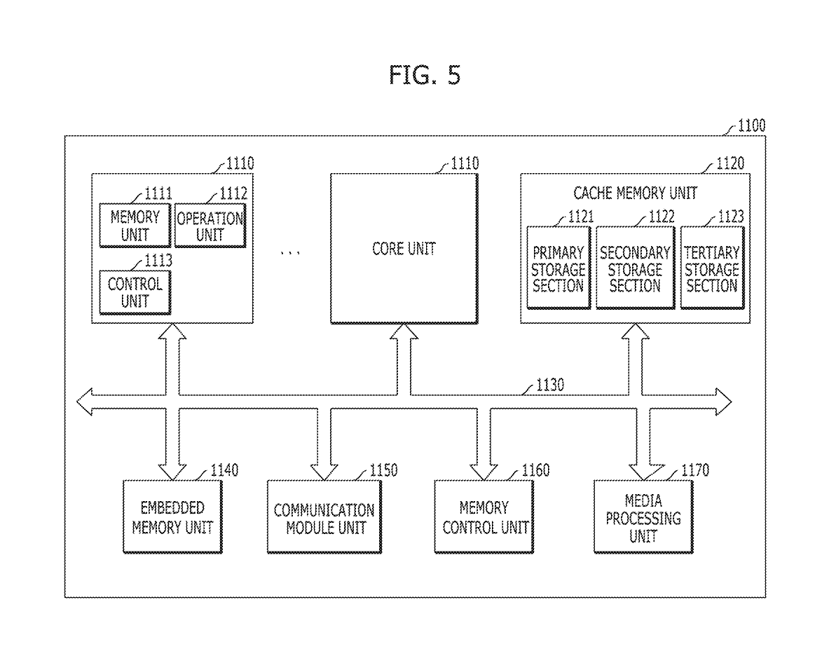

FIG. 6 is an example of configuration diagram of a system implementing memory circuitry based on the disclosed technology.

Referring to FIG. 6, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 may include a substrate; a variable resistance element that is disposed over the substrate; a hard mask pattern that is disposed over the variable resistance element and includes a metal; and a spacer that is disposed on a sidewall of the variable resistance element, wherein the spacer includes an oxide of a first material that is more readily oxidized than the metal of the hard mask pattern. Through this, data storage characteristics and operating characteristics of the main memory device 1220 may be improved. As a consequence, operating characteristics of the system 1200 may be improved.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 may include a substrate; a variable resistance element that is disposed over the substrate; a hard mask pattern that is disposed over the variable resistance element and includes a metal; and a spacer that is disposed on a sidewall of the variable resistance element, wherein the spacer includes an oxide of a first material that is more readily oxidized than the metal of the hard mask pattern. Through this, data storage characteristics and operating characteristics of the auxiliary memory device 1230 may be improved. As a consequence, operating characteristics of the system 1200 may be improved.

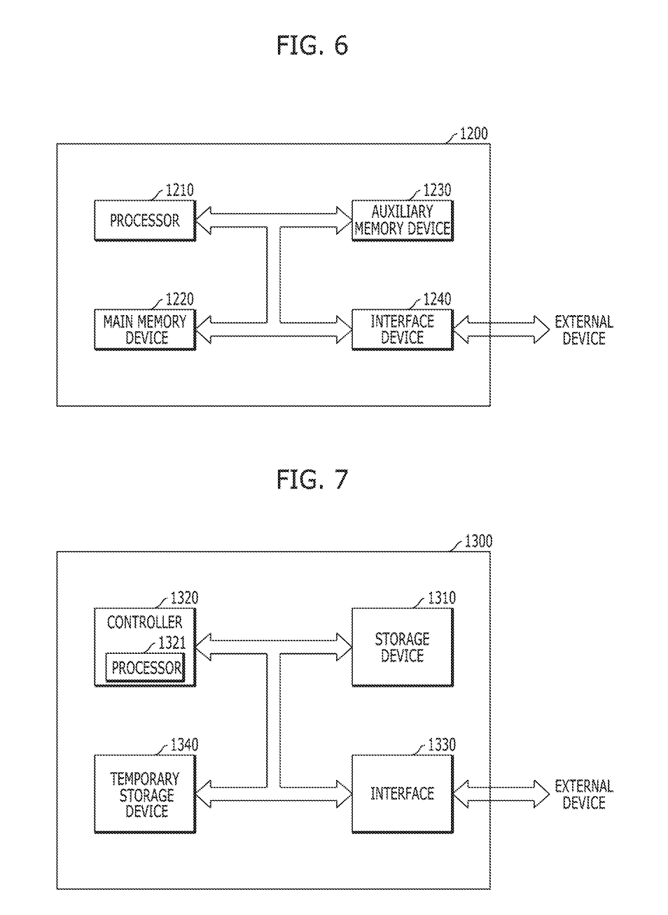

Also, the auxiliary memory device 1230 may further include a data storage system (see the reference numeral 1300 of FIG. 7) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 7) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device, and so on. The communication device may include a module capable of being connected with a wired network, a module capable of being connected with a wireless network and both of them. The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 7 is an example of configuration diagram of a data storage system implementing memory circuitry based on the disclosed technology.

Referring to FIG. 7, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MIVIC), an embedded MMC (eMIVIC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other.

The temporary storage device 1340 can store data temporarily for efficiently transferring data between the interface 1330 and the storage device 1310 according to diversifications and high performance of an interface with an external device, a controller and a system. The temporary storage device 1340 for temporarily storing data may include one or more of the above-described semiconductor devices in accordance with the implementations. The temporary storage device 1340 may include a substrate; a variable resistance element that is disposed over the substrate; a hard mask pattern that is disposed over the variable resistance element and includes a metal; and a spacer that is disposed on a sidewall of the variable resistance element, wherein the spacer includes an oxide of a first material that is more readily oxidized than the metal of the hard mask pattern. Through this, data storage characteristics and operating characteristics of the storage device 1310 or the temporary storage device 1340 may be improved. As a consequence, operating characteristics and data storage characteristics of the data storage system 1300 may be improved.

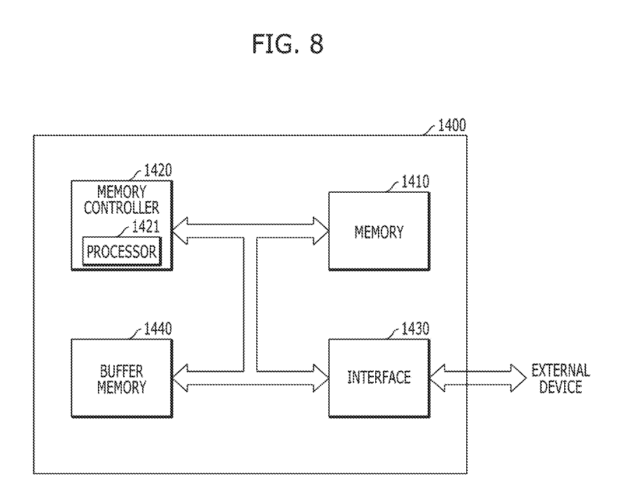

FIG. 8 is an example of configuration diagram of a memory system implementing memory circuitry based on the disclosed technology.

Referring to FIG. 8, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the implementations. For example, the memory 1410 may include a substrate; a variable resistance element that is disposed over the substrate; a hard mask pattern that is disposed over the variable resistance element and includes a metal; and a spacer that is disposed on a sidewall of the variable resistance element, wherein the spacer includes an oxide of a first material that is more readily oxidized than the metal of the hard mask pattern. Through this, data storage characteristics and operating characteristics of the memory 1410 may be improved. As a consequence, operating characteristics and data storage characteristics of the memory system 1400 may be improved.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more of the above-described semiconductor devices in accordance with the implementations. The buffer memory 1440 may include a substrate; a variable resistance element that is disposed over the substrate; a hard mask pattern that is disposed over the variable resistance element and includes a metal; and a spacer that is disposed on a sidewall of the variable resistance element, wherein the spacer includes an oxide of a first material that is more readily oxidized than the metal of the hard mask pattern. Through this, data storage characteristics and operating characteristics of the buffer memory 1440 may be improved. As a consequence, operating characteristics and data storage characteristics of the memory system 1400 may be improved.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

Features in the above examples of electronic devices or systems in FIGS. 4-8 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. A method for fabricating an electronic device including a semiconductor memory, comprising:
forming a variable resistance element including material layers over a substrate;
forming a hard mask layer including a metal over the material layers;
selectively etching the hard mask layer to form an etched hard mask layer;
etching the material layers by using the etched hard mask layer as an etch barrier, the etching of the material layers providing an etch byproduct formed on sidewalls of the etched material layers and the etch byproduct including a material that is more readily oxidized than the metal of the hard mask layer; and
performing a treatment using a gas or plasma to suppresses oxidation of the hard mask layer and facilitate oxidation of the etch byproducts.

2. The method according to claim 1, wherein the etch byproduct includes a material whose electron affinity is lower than the metal of the hard mask layer.

3. The method according to claim 1, wherein the etch byproduct includes a material having a standard electrode potential ranging from approximately −2V to approximately −0.5V, and
the hard mask layer includes a metal having a standard electrode potential ranging from approximately −0.5V to approximately −0.0V.

4. The method according to claim 1, wherein the etch byproduct includes Si, Ge, Nd, Sc, Th, Be, Al, Ti, Hf, Pa, Zr, Mn, V, Nb, Cr, Zn, or Ta, or a combination thereof, and
the hard mask layer includes Mo, Sn, Pb, W, or Re, or a combination thereof.

5. The method according to claim 1, wherein the gas or plasma contains oxygen and at least one of hydrogen, nitrogen, or carbon.

6. The method according to claim 1, wherein the performing of the treatment includes performing an H₂O Inductive Coupled Plasma (ICP) treatment.

7. The method according to claim 1, wherein the forming of the variable resistance element includes:
forming a Magnetic Tunnel Junction (MTJ) structure that includes a free layer whose magnetization direction is changeable, a pinned layer whose magnetization direction is fixed, and a tunnel barrier layer which is interposed between the free layer and the pinned layer.

8. The method according to claim 1, further including: forming a lower layer pattern over the substrate to be coupled to the variable resistance element, and
include a same material as the etch byproduct.

9. The method according to claim 8, wherein an upper surface of the lower layer pattern is greater than a lower surface of the variable resistance element.
